(19) United States
(12) Patent Application Publication
(10) Pub. No.: US 2026/0132813 A1
(43) Pub. Date: May 14, 2026

(54) HINGE ASSEMBLY AND ELECTRONIC DEVICE COMPRISING SAME

(71) Applicant: Samsung Electronics Co., Ltd., Suwon-si (KR)

(72) Inventor: Myoungkyu LEE, Suwon-si (KR)

(21) Appl. No.: 19/432,667

(22) Filed: Dec. 24, 2025

Related U.S. Application Data
(63) Continuation of application No. PCT/KR2024/007904, filed on Jun. 10, 2024.

(30) Foreign Application Priority Data
Jul. 28, 2023 (KR) 10-2023-0098619
Sep. 11, 2023 (KR) 10-2023-0120390

(51) Int. Cl. F16C 11/04; H05K 5/02

(52) U.S. Cl. CPC F16C 11/04; H05K 5/0226

(57) ABSTRACT

A hinge assembly is provided. The hinge assembly includes a fixing member including a hollow shaft extending along a directed of a hinge axis, a shaft accommodated at least partially in the hollow shaft and configured to rotate around the hinge axis, a bracket coupled to surround at least a portion of the hollow shaft and configured to rotate around the hinge axis, and at least one link member, wherein a portion of the at least one link member is coupled to the shaft and another portion of the at least one link member is fixed to the bracket, wherein the shaft and the bracket are connected through the at least one link member so as to rotate together with respect to the hollow shaft.

### CROSS-REFERENCE TO RELATED APPLICATIONS

This application is a continuation application, claiming priority under 35 U.S.C. § 365(c), of an International application No. PCT/KR2024/007904, filed on June 10, 2024, which is based on and claims the benefit of a Korean patent application number 10-2023-0098619, filed on July 28, 2023, in the Korean Intellectual Property Office, and of a Korean patent application number 10-2023-0120390, filed on September 11, 2023, in the Korean Intellectual Property Office, the disclosure of each of which is incorporated by reference herein in its entirety.

### BACKGROUND

### 1. Field

The disclosure relates to an electronic device. More particularly, the disclosure relates to a hinge assembly and/or an electronic device including the same.

### 2. Description of Related Art

Typically, the term 'electronic device' may be used to mean devices that enable use of communication functions such as voice calls or short message transmission, multimedia functions such as music or video playback, and entertainment functions such as games. Such electronic devices may include desktop computers used in homes or offices, and laptop computers that have enhanced portability and space utilization in general use environments including homes or offices.

In enhancing portability and space utilization, an electronic device including a plurality of housings or an electronic device including a flexible display may be useful. For example, while in use, the housings may be unfolded to provide an extended screen or an input device, and the housings may be folded or rolled up for carrying or storage. By incorporating a touchscreen function in an output device such as a display, thereby replacing an input device such as a keyboard (or keypad), the electronic devices such as smartphones or tablet personal computers (PCs) have become usable while being carried around daily. Even though the use of electronic devices such as smartphones has become routine, demand for electronic devices such as laptop computers still exists depending on production costs or usage purposes, and efforts for miniaturization or weight reduction continue in these office or home electronic devices.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a hinge assembly and/or an electronic device including the same.

Additional aspects will be set forth in part in the description which follows and, in part, will be apparent from the description, or may be learned by practice of the presented embodiments.

In accordance with an aspect of the disclosure, a hinge assembly is provided. The hinge assembly includes a fixing member including a hollow shaft extending along a direction of a hinge axis, a shaft accommodated at least partially in the hollow shaft and configured to rotate around the hinge axis within the hollow shaft, a bracket coupled to surround at least a portion of the hollow shaft and configured to rotate around the hinge axis, and at least one link member, wherein a portion of the at least one link member is coupled to the shaft and another portion of the at least one link member is fixed to the bracket, wherein the shaft and the bracket are connected through the at least one link member to rotate together with respect to the hollow shaft.

In accordance with another aspect of the disclosure, an electronic device is provided. The electronic device includes a first housing, a second housing configured to pivot around a hinge axis between a first position facing the first housing and a second position unfolded by a designated angle from the first position, and a hinge assembly rotatably coupling the first housing and the second housing, the hinge assembly including a fixing member disposed at least partially in one of the first housing and the second housing and including a hollow shaft extending along the direction of the hinge axis, a shaft accommodated at least partially in the hollow shaft and configured to rotate around the hinge axis within the hollow shaft, a bracket disposed at least partially in the other one of the first housing and the second housing and coupled to surround at least a portion of the hollow shaft and configured to rotate around the hinge axis, and at least one link member, wherein a portion of the at least one link member is coupled to the shaft and another portion of the at least one link member is fixed to the bracket, wherein the shaft and the bracket are connected through the at least one link member to rotate together with respect to the hollow shaft.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment of the disclosure;

FIG. 2 is a perspective view illustrating an electronic device according to an embodiment of the disclosure;

FIG. 3 is a perspective view illustrating an unfolded state of the electronic device of FIG. 2, according to an embodiment of the disclosure;

FIG. 4 is a side view illustrating an arrangement of the hinge assembly of the electronic device of FIG. 2, according to an embodiment of the disclosure;

FIG. 5 is a plan view illustrating an arrangement of the hinge assembly of the electronic device of FIG. 2, according to an embodiment of the disclosure;

FIG. 6 is an exploded perspective view illustrating a hinge assembly of an electronic device according to an embodiment of the disclosure;

FIG. 7 is a perspective view illustrating a fixing member in the hinge assembly of FIG. 6, according to an embodiment of the disclosure;

FIG. 8 is a perspective view illustrating assembly of a shaft and/or a bracket with a fixing member in the hinge assembly of FIG. 6, according to an embodiment of the disclosure;

FIG. 9 is a perspective view illustrating assembly of link member(s) in the hinge assembly of FIG. 6, according to an embodiment of the disclosure;

FIG. 10 is a perspective view illustrating a hinge assembly according to an embodiment of the disclosure;

FIG. 11 is a view illustrating operation of a hinge assembly according to an embodiment of the disclosure;

FIG. 12 is a view illustrating a portion of a hinge assembly, sectioned along line A-A' of FIG. 10, according to an embodiment of the disclosure;

FIG. 13 is a perspective view illustrating a fixing member and/or a shaft of a hinge assembly according to an embodiment of the disclosure;

FIG. 14 is a view illustrating a state in which a shaft is assembled to a fixing member of a hinge assembly according to an embodiment of the disclosure;

FIG. 15 is a perspective view illustrating a hinge assembly according to an embodiment of the disclosure;

FIG. 16 is a perspective view illustrating a hinge assembly according to an embodiment of the disclosure;

FIG. 17 is a view illustrating an unfolded state of an electronic device according to an embodiment of the disclosure;

FIG. 18 is a view illustrating a folded state of an electronic device according to an embodiment of the disclosure; and

FIG. 19 is an exploded perspective view illustrating an electronic device according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding, but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but are merely used by the inventor to enable a clear and consistent understanding of the disclosure. Accordingly, it should be apparent to those skilled in the art that the following description of various embodiments of the disclosure is provided for illustration purposes only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

An electronic device may be implemented with a structure in which a plurality of housings are combined to be foldable or unfoldable by including a hinge assembly. Various components such as an input device, an output device, a processor, memory, and a communication module may be appropriately disposed in the housings, thereby enhancing usability or portability of the electronic device. One of the housings connected through the hinge assembly (e.g., a housing equipped with an input device such as a keyboard) may be disposed on a flat surface such as a table, and the other (e.g., a housing equipped with an output device such as a display) may be disposed facing the user in an unfolded state at a designated angle with respect to the housing disposed on the flat surface. Maintaining the relative angle of these housings in a use state may be an indicator for evaluating the mechanical stability of the hinge assembly and/or the mechanical stability of an electronic device including a plurality of housings. However, in an environment where electronic devices are becoming increasingly lighter or thinner, it may be difficult to implement a hinge assembly that mechanically couples the housings while providing sufficient mechanical stability to maintain a folded state or an unfolded state.

An embodiment of the disclosure is intended to at least resolve the above-described problems and/or disadvantages and to provide at least the advantages described below, and may provide a hinge assembly having mechanical stability and/or an electronic device including the same.

An embodiment of the disclosure may provide a hinge assembly that may more stably maintain the mounting state of the housings when manufactured in substantially the same size and/or an electronic device including the same.

An embodiment of the disclosure may provide a hinge assembly that may be downsized while stably maintaining the mounting state of the housings and/or an electronic device including the same.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

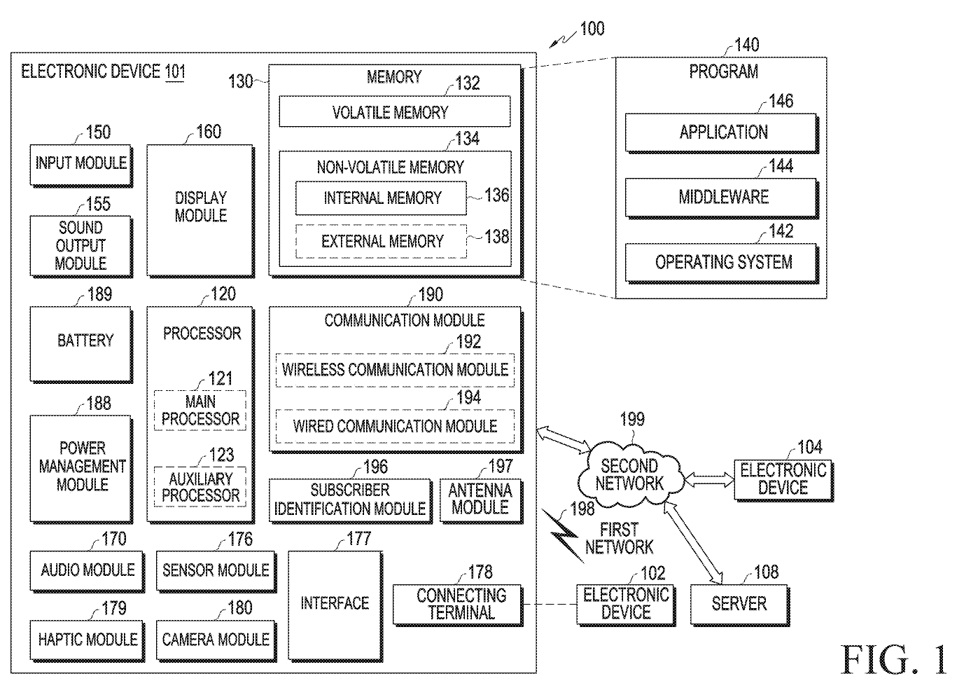

FIG. 1 is a block diagram illustrating an electronic device 101 in a network environment 100 according to an embodiment of the disclosure.

Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., the program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operation state (e.g., power or temperature) of the electronic device 101 or an external environmental state (e.g., the user's state), and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via a first network 198 (e.g., a short-range communication network, such as Bluetooth^{TM}, wireless-fidelity (Wi-Fi) direct, or infrared data association (IrDA)) or a second network 199 (e.g., a long-range communication network, such as a legacy cellular network, a fifth generation (5G) network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or U-plane latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device). According to an embodiment, the antenna module may include an antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to embodiment(s) of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

An embodiment of the disclosure and terms used therein are not intended to limit the technical features described in the disclosure to specific embodiments, and should be understood to include various modifications, equivalents, or substitutes of the embodiment. In this document, phrases such as "A or B", "at least one of A and B", "at least one of A or B", "A, B or C", "at least one of A, B and C", and "at least one of A, B, or C" may each include any one of the items listed together in the corresponding phrase, or all possible combinations thereof. As used herein, such terms as "1st" and "2nd," or “first” and "second" may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” "coupled to," "connected with," or “connected to” another element (e.g., a second element), it means that the element may be coupled with the other element directly (e.g., wiredly), wirelessly, or via a third element.

As used herein, the term "module" may include a unit implemented in hardware, software, or firmware, and may interchangeably be used with other terms, for example, "logic," "logic block," "part," or "circuitry". A module may be a single integral component, or a minimum unit or part thereof, adapted to perform one or more functions. For example, according to an embodiment, the module may be implemented in a form of an application-specific integrated circuit (ASIC).

Embodiments as set forth herein may be implemented as software (e.g., the program) including one or more instructions that are stored in a storage medium (e.g., internal memory or external memory) that is readable by a machine (e.g., the electronic device). For example, a processor (e.g., the processor) of the machine (e.g., the electronic device) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the term "non-transitory" simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiment(s) of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store^{TM}), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

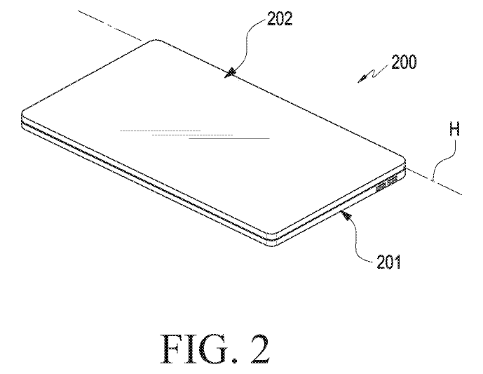

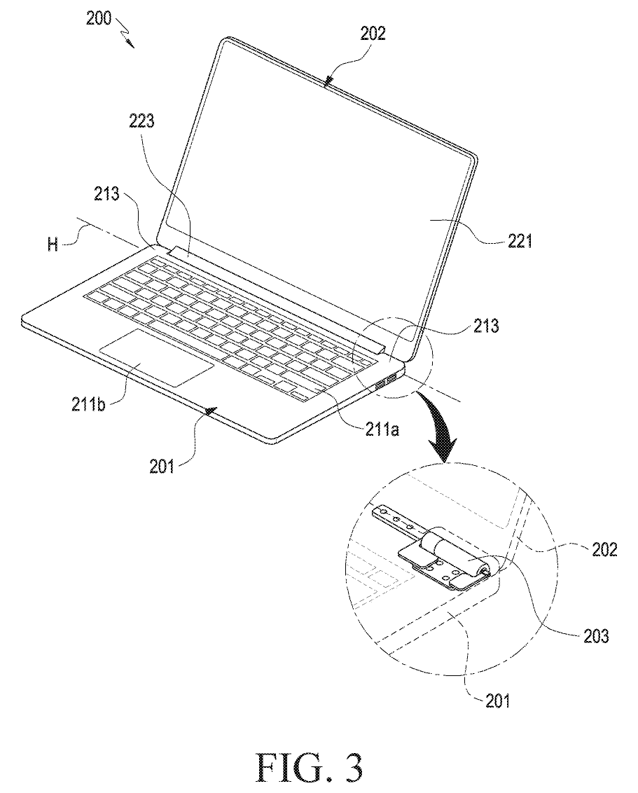

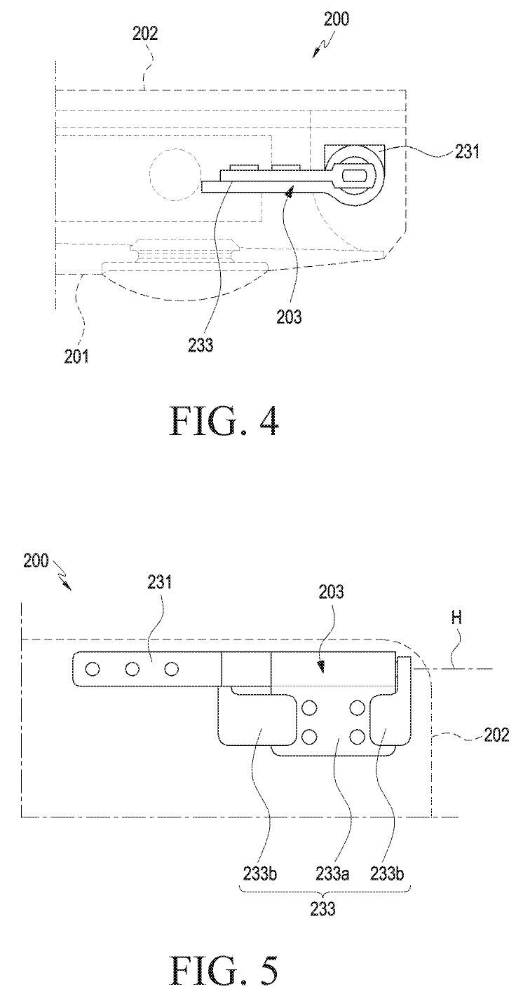

FIG. 2 is a perspective view illustrating an electronic device according to an embodiment of the disclosure. FIG. 3 is a perspective view illustrating an unfolded state of the electronic device of FIG. 2, according to an embodiment of the disclosure. FIG. 4 is a side view illustrating an arrangement of the hinge assembly of the electronic device of FIG. 2, according to an embodiment of the disclosure. FIG. 5 is a plan view illustrating an arrangement of the hinge assembly of the electronic device of FIG. 2, according to an embodiment of the disclosure.

Referring to FIGS. 2 to 5, an electronic device 200 (e.g., the electronic device 101, 102, 104 of FIG. 1) according to an embodiment of the disclosure may include a first housing 201, a second housing 202, and/or a hinge assembly 203. The hinge assembly 203 is disposed between the first housing 201 and the second housing 202 and may provide a hinge axis H extending in one direction. For example, the first housing 201 and/or the second housing 202 may pivot around the hinge axis provided by the hinge assembly between a first position facing each other (e.g., the state illustrated in FIG. 2) and a second position unfolded by a designated angle from the first position.

The 'designated angle' may be generally within 180 degrees, and the second housing 202 may be stopped in an inclined state with respect to the first housing 201 at any angular position within the designated angle range. The state in which the second housing 202 is stopped with respect to the first housing 201 may be maintained by torque or static friction force provided by the hinge assembly 203. According to an embodiment of the disclosure, the 'designated angle' may be about 360 degrees. For example, the second housing 202 may be rotated about 360 degrees from the first position folded to face the upper surface of the first housing 201 to be folded to face the lower surface of the first housing 201. When defined that the display 221 disposed in the second housing 202 is concealed in the first position, the display 221 may be visually exposed to the external space when the second housing 202 is rotated about 360 degrees from the first position.

The first housing 201 may be understood as a main body or main housing, and may incorporate electronic components such as a processor (e.g., the processor 120 of FIG. 1), a battery (e.g., the battery 189 of FIG. 1), memory (e.g., the memory 130 of FIG. 1), and/or a communication module (e.g., the communication module 190 of FIG. 1), along with input devices 211a and 211b. Examples of the input devices 211a and 211b include a keyboard 211a and a touchpad 211b.

The second housing 202 as a sub housing is rotatably coupled to one edge of the first housing 201 and may incorporate electronic components such as a sensor module (e.g., the sensor module 176 of FIG. 1), a camera module (e.g., the camera module 180 of FIG. 1), or an antenna module (e.g., the antenna module 197 of FIG. 1), along with an output device (e.g., display 221). An example of the output device may be the display 221. When equipped with a touchscreen function, the display 221 may be understood as both an output device and an input device. For example, the keyboard 211a or touchpad 211b of FIG. 3 may be replaced with a touchscreen display. In this case, the electronic device 200 may include a flexible display providing a first display area disposed in the first housing and a second display area extending from the first display area and disposed in the second housing.

The display 221 of FIG. 3 may be implemented as a flexible display that is extended beyond what is illustrated to extend to the first housing 201. For example, the electronic device 200 may include a flexible display disposed from the first housing 201 to the second housing 202. The flexible display generally functions as an output device providing visual information and may function as an input device by including a touchscreen function in at least a partial area (e.g., the area disposed in the first housing 201).

The hinge assembly 203 may rotatably couple the first housing 201 and the second housing 202 to each other with one edge of the first housing 201 and/or the second housing 202 adjacent to each other. For example, the hinge axis H may be implemented at one edge of the first housing 201 and/or the second housing 202. According to an embodiment of the disclosure, a pair of hinge assemblies 203 may be disposed at different positions at a designated interval to rotatably couple the first housing 201 and the second housing 202. In the embodiment illustrated in FIG. 3, the pair of hinge assemblies 203 may be disposed at least partially in the corresponding one of the hinge arms 213.

The first housing 201 may include hinge arms 213 provided at two opposite ends of one edge. The hinge arms 213 are disposed on the hinge axis H, and a portion of the second housing 202 (hereinafter, hinge portion 223) may be disposed between the hinge arms 213. For example, the hinge portion 223 may rotate around the hinge axis H between the hinge arms 213, whereby the second housing 202 may pivot around the hinge axis H. The hinge assembly 203 may rotatably couple the first housing 201 and the second housing 202 by having a portion (e.g., the rotating member 233) fixed to one of the first housing 201 and the second housing 202, and another portion (e.g., the fixing member 231) fixed to the other one of the first housing 201 and the second housing 202.

In the embodiment illustrated in FIGS. 4 and 5, the fixing member 231 of the hinge assembly 203 is fixed inside the second housing 202 (e.g., the hinge portion 223), and the rotating member 233 (e.g., the bracket 233a and link member(s) 233b) is fixed to the first housing 201 (e.g., one of the hinge arms 213). As will be described below, the fixing member 231 and the rotating member 233 are structures rotatably coupled to each other, and the rotation of the first housing 201 and the second housing 202 with respect to each other may be understood as substantially the rotation of the fixing member 231 and the rotating member 233 with respect to each other.

In describing the embodiment(s) of the disclosure, although a portion of the hinge assembly 203 is referred to as a fixing member 231 and another portion as a rotating member 233, this is for distinguishing components in describing the hinge assembly 203, and it should be noted that the embodiment(s) of the disclosure are not limited thereto. For example, saying 'the rotating member 233 rotates (or pivots)' is based on the fixing member 231 in describing the operation of the hinge assembly 203, and the same expression may be understood as the fixing member 231 rotating or pivoting with respect to the rotating member 233. Therefore, it should be noted that even when referred to as fixing member 231, the component indicated by reference number 231 may pivot with respect to another component (e.g., the rotating member 233). According to an embodiment of the disclosure, the fixing member 231 may be described as a first hinge member, and/or the rotating member 233 may be described as a second hinge member. For example, it should be noted that in describing the embodiment(s) of the disclosure, the operation or function of the components is not limited by the names of such components.

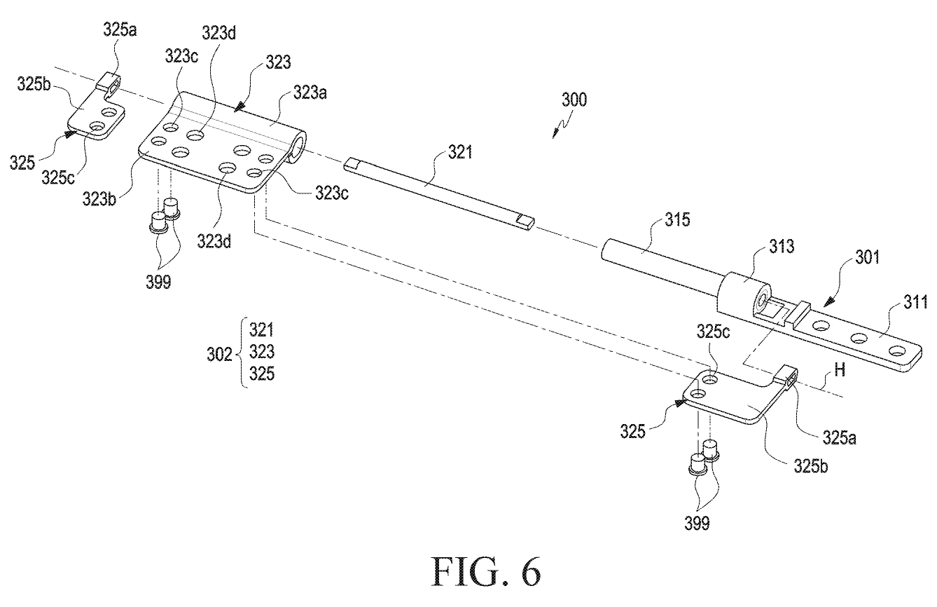

The fixing member 231 may be substantially fixed inside the hinge portion 223 and may be partially disposed inside the hinge arm(s) 213. For example, the rotating member 233 fixed to the first housing 201 inside the hinge arm(s) 213 may rotate (or pivot) around the hinge axis H by coupling to surround a portion of the fixing member 231 inside the hinge arm(s) 213. In an embodiment, the rotating member 233 may rotate around the hinge axis H by including a bracket 233a substantially coupled to surround a portion of the fixing member 231 and/or a shaft (not illustrated) (e.g., the shaft 321 of FIG. 6), and the bracket 233a and the shaft 321 may be connected by link member(s) 233b to rotate together with respect to the fixing member 231.

More specific configurations of the hinge assembly 203 are described below with reference to FIGS. 6 to 15. Any of the electronic devices 101, 102, 104, 200 and/or hinge assemblies 203 of the preceding embodiments may be used with respect to the embodiments described below.

FIG. 6 is an exploded perspective view illustrating a hinge assembly (e.g., the hinge assembly of FIGS. 3 to 5) of an electronic device (e.g., the electronic device of FIGS. 1 to 5) according to an embodiment of the disclosure.

Referring to FIG. 6, the hinge assembly 300 (e.g., the hinge assembly 203 of FIGS. 3 to 5) may include a rotating member 302 (e.g., the rotating member 233 of FIGS. 3 to 5) and a fixing member 301 (e.g., the fixing member 231 of FIGS. 3 to 5). The rotating member 302 may be implemented, e.g., as a combination of a shaft 321, a bracket 323 (e.g., the bracket 233a of FIG. 5), and/or link member(s) 325 (e.g., the link member 233b of FIG. 5). The shaft 321 may be received at least partially inside the fixing member 301 (e.g., the hollow shaft 315), and the bracket 323 may be coupled to surround at least a portion of the fixing member 301 at the portion where the shaft 321 is received.

An environment may be created where friction force may be generated on the outer circumferential surface of the shaft 321 and/or the inner circumferential surface of a portion of the bracket 323. Such friction force may be proportional to the directly contacted area between two components, for example. The contact area between the rotating member 302 and the fixing member 301 may be understood as the outer circumferential surface area of the shaft 321 and the inner circumferential surface area of a portion of the bracket 323 (e.g., the sleeve 323a). For example, the hinge assembly 300 may provide a wide area for generating friction force by configuring the shaft 321 and the bracket 323 to rotate with respect to the fixing member 301 (e.g., the hollow shaft 315). Between the rotating member 302 and the fixing member 301, the friction force generated by the outer circumferential surface of the shaft 321 and/or the inner circumferential surface of a portion of the bracket 323 may maintain the housings (e.g., the first housing 201 and second housing 202 of FIG. 2 or 3) in a folded state or stopped at an angle required by the user with respect to each other.

The shaft 321 may be a rod extending in one direction and may be disposed substantially coincident with or parallel to the hinge axis H. For example, the shaft 321 may be received in the fixing member 301 (e.g., the hollow shaft 315) in a state capable of rotating (e.g., self-rotating) around the hinge axis H. At the portion received in the fixing member 301, the shaft 321 may have a circular cross-section, thereby providing a wide contact area with the fixing member 301 during rotation. Similarly, by providing the space where the shaft 321 is received in a cylindrical shape, the shaft 321 and the fixing member 301 may be in substantial surface contact.

As will be described below, the shaft 321 may be coupled with the link member(s) and constrained to each other with the link member 325 in the rotational direction. For example, an end of the shaft 321 may be exposed outside the fixing member 301, and at least a portion of the outer circumferential surface of the exposed portion may have a flat shape rather than a curved surface (e.g., the first D-shaped plane 321a of FIG. 8). The end of the shaft 321 may be positioned substantially inside the space provided by the fixing member 301, and a portion of the link member(s) 325 may be bound to the end of the shaft 321 inside the space of the fixing member 301.

The bracket 323 may include a sleeve 323a and a first fixing plate 323b. The bracket 323 may be, for example, a plate with one edge processed (or rolled) into a tubular shape, where the portion processed into a tubular shape may be provided as the sleeve 323a and the remaining portion may be provided as the first fixing plate 323b. It may be understood that the first fixing plate 323b extends to one side from the sleeve 323a. The sleeve 323a may be in the shape of a cylindrical tube extending along one direction (e.g., the direction of hinge axis H) and may be coupled to surround a portion of the fixing member 301 (e.g., the hollow shaft 315) while aligned with the hinge axis H. The inner circumferential surface of the sleeve 323a and/or a portion of the fixing member 301 (e.g., the portion surrounded by a portion of the bracket 323 (e.g., the sleeve 323a)) may have a circular cross-section. For example, similar to the shaft 321, sufficient contact area or friction force may be secured for the sleeve 323a or a portion of the fixing member 301 (e.g., the portion wrapped by the sleeve 323a) during rotation.

The rotating member 302 and/or bracket 323 may include first fastening hole(s) 323c for binding with the link member(s) 325 and/or second fastening hole(s) 323d for binding or fixing inside one of the housings 201 or 202. The link member(s) 325 may be bound to the shaft 321 and coupled to at least partially face the bracket 323 (e.g., the first fixing plate 323b). For example, by being linked through the link member(s) 325, the shaft 321 and the bracket 323 may rotate substantially simultaneously with respect to the fixing member 301.

The first fastening hole(s) 323c may be disposed on the first fixing plate 323b in an area facing the link member(s) 325, and fastening member(s) 399 (e.g., rivet(s)) may bind or fix the link member(s) 325 in a state facing the first fixing plate 323b). Although rivets are illustrated as the fastening member 399 in the illustrated embodiment, other fastening members such as screws or bolts may be used. According to another embodiment of the disclosure, the fastening member 399 may be omitted and the link member(s) 325 may be fixed to the bracket 323 (e.g., the first fixing plate 323b) by a bonding structure or welding structure.

The link member(s) 325 may include a hub portion 325a bound or fixed to one of two opposite ends of the shaft 321, and a second fixing plate 325b extending from the hub portion 325a. The second fixing plate 325b may be understood, as a portion disposed to at least partially face the first fixing plate 323b. For example, when the link member(s) 325 and the bracket 323 are fixed to each other, the fastening member 399 may be bound or fixed by passing through the first fixing plate 323b and the second fixing plate 325b.

The second fixing plate 325b may include a third fastening hole 325c aligned to face the first fastening hole 323c and/or receiving at least a portion of the fastening member 399. For example, the fastening member 399 may pass through the first fastening hole 323c and the third fastening hole 325c to fix the first fixing plate 323b and the second fixing plate 325b to each other. In the illustrated embodiment, a configuration is illustrated where link members 325 are provided at two opposite ends of the shaft 321, respectively, and coupled to the bracket 323 (e.g., the first fixing plate 323b). For example, in rotating the shaft 321 and the bracket 323 substantially simultaneously on the fixing member 301 (e.g., the hollow shaft 315), the rotation operation may be further stabilized by providing a pair of link members 325.

Although not given reference numbers, the link member(s) 325 may include a binding hole receiving one end of the shaft 321. The binding hole may have a shape corresponding to the end of the shaft 321 (e.g., a shape including the first D-shaped plane 321a), e.g., whereby the link member(s) 325 may be constrained to the shaft 321 in the rotational direction. In an embodiment, the shaft 321, sleeve 323a, and/or hub portion 325a may be understood as rotating around the hinge axis H, and the first fixing plate 323b and/or second fixing plate 325b may be understood as pivoting around the hinge axis H. In the embodiments described below, the rotation operation or pivoting operation may be referred to as substantially the same operation.

The fixing member 301 may include a third fixing plate 311 extending in one direction and a hollow shaft 315. The hollow shaft 315 is substantially in the shape of a cylindrical tube and may receive at least a portion of the shaft 321. In disposing the hollow shaft 315, the fixing member 301 may further include a fixing boss 313 provided on the third fixing plate 311, and one end of the hollow shaft 315 may be fixed to the fixing boss 313. An adhesive may be utilized in coupling the hollow shaft 315 to the fixing boss 313. However, it should be noted that the embodiment(s) of the disclosure are not limited thereto. For example, the hollow shaft 315 may be disposed substantially coincident with the hinge axis H, and the third fixing plate 311 may be disposed parallel to the hinge axis H at a designated interval. For example, when the second housing 202 pivots with respect to the first housing 201, the third fixing plate 311 may be understood as revolving around the hinge axis H.

In the electronic device 200 of FIGS. 2 to 5, the fixing members 231 or 301 (e.g., the third fixing plate 311) may be substantially fixed inside the second housing 202 (e.g., inside the hinge portion 223) and may dispose the hollow shaft 315 inside the first housing 201 (e.g., inside one of the hinge arms 213) while aligned with the hinge axis H. Although not given reference numbers, the fixing member 301 includes fastening holes passing through the third fixing plate 311, and in fixing the fixing member 301 to one of the housings 201 or 202 (e.g., the second housing 202), the fastening holes of the third fixing plate 311 may be utilized. The rotating member 302 (e.g., the shaft 321, bracket 323, and/or link member(s) 325) may be rotatably disposed on the hollow shaft 315 while being substantially fixed inside the first housing 201. In fixing the rotating member 302 inside the first housing 201, a fastening member (not illustrated) (e.g., screw) may pass through the second fastening hole 323d to be fastened to an internal structure (e.g., fastening boss) of the first housing 201.

The third fixing plate 311 may be disposed inside one of the hinge arms 213 while disposing the hollow shaft 315 inside the hinge portion 223. For example, although the third fixing plate 311 is illustrated as being disposed in the second housing 202 (e.g., the hinge portion 223) in the illustrated embodiment, it should be noted that the disclosure is not limited by the illustrated embodiment in disposing the hinge assembly 300 on the housings 201, 202.

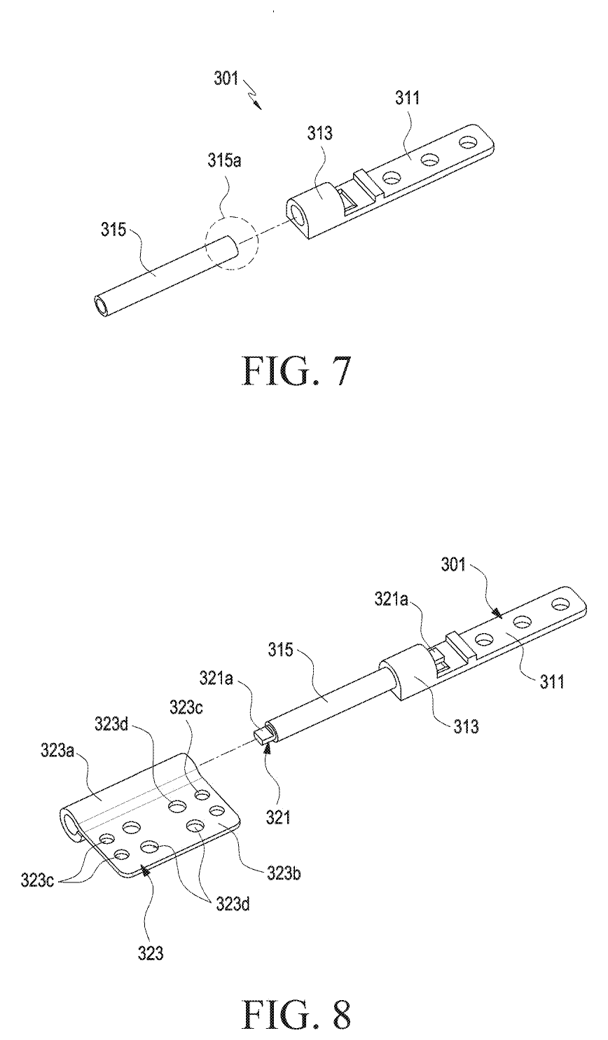

An assembly structure of the above-described hinge assemblies 203 are 300 is described below with reference to FIGS. 7 to 11. Since the configuration or assembly structure of the hinge assemblies 203 and 300 described below may be similar to the above-described embodiment, reference numbers in the drawings may be allocated identically or omitted. In assembling the components of the hinge assemblies 203 and 300, it should be noted that the arrangement order or assembly order of the drawings described below does not limit the embodiments of the disclosure, and the assembly order may differ according to the specifications of the hinge assemblies 203 and 300 to be actually manufactured.

FIG. 7 is a perspective view illustrating a fixing member in the hinge assembly of FIG. 6, according to an embodiment of the disclosure.

Referring to FIG. 7, the fixing member 301 may be implemented by combining the third fixing plate 311 (and/or fixing boss 313) and the hollow shaft 315. For example, by inserting one end 315a of the hollow shaft 315 into the fixing boss 313 along the direction of the hinge axis H, the hollow shaft 315 may be aligned or assembled in a state substantially parallel to the third fixing plate 311 and substantially coincident with the hinge axis H. The hollow shaft 315 may be fixed to the fixing boss 313 (and/or third fixing plate 311) in a non-rotatable state. For example, even when the rotating member 302 rotates, the hollow shaft 315 generates friction force by maintaining a fixed state, thereby providing static friction force to maintain the housings in a stopped state at an angular position required by the user. In being coupled to the fixing boss 313 in a non-rotatable state, the hollow shaft 315 may include a D-shaped plane (e.g., the second D-shaped plane 415b of FIG. 14) formed on the outer circumferential surface of the end 315a. The planar structure for constraint in the rotational direction may be similar to the coupling structure between the shaft 321 and the link member 325 described above, so detailed description thereof is omitted.

FIG. 8 is a perspective view illustrating a shaft and/or bracket being assembled to the fixing member in the hinge assembly of FIG. 6, according to an embodiment of the disclosure.

Referring to FIG. 8, the shaft 321 may be substantially received in the hollow shaft 315 to protrude two opposite ends (e.g., portions where the first D-shaped plane is formed) from two opposite ends of the hollow shaft 315, respectively. In an embodiment, one end of the shaft 321 may be understood as protruding from one side of the fixing boss 313. By disposing the outer circumferential surface of the shaft 321 and the inner circumferential surface of the hollow shaft 315 in substantial contact, static friction force may be provided to maintain the housings 201 and 202 in a stopped state at an angular position according to user requirements.

A portion of the bracket 323 (e.g., the sleeve 323a) may be rotatably coupled in a state surrounding the hollow shaft 315. For example, by disposing the outer circumferential surface of the hollow shaft 315 and the inner circumferential surface of the sleeve 323a in substantial contact, static friction force may be provided to maintain the housings 201, 202 in a stopped state at an angular position according to user requirements. When the shaft 321 and/or sleeve 323a rotates with respect to the hollow shaft 315, the first fixing plate 323b may be understood as pivoting around the hollow shaft 315. As mentioned earlier, the pivoting of the first fixing plate 323b may be referred to as a rotation of the first fixing plate 323b.

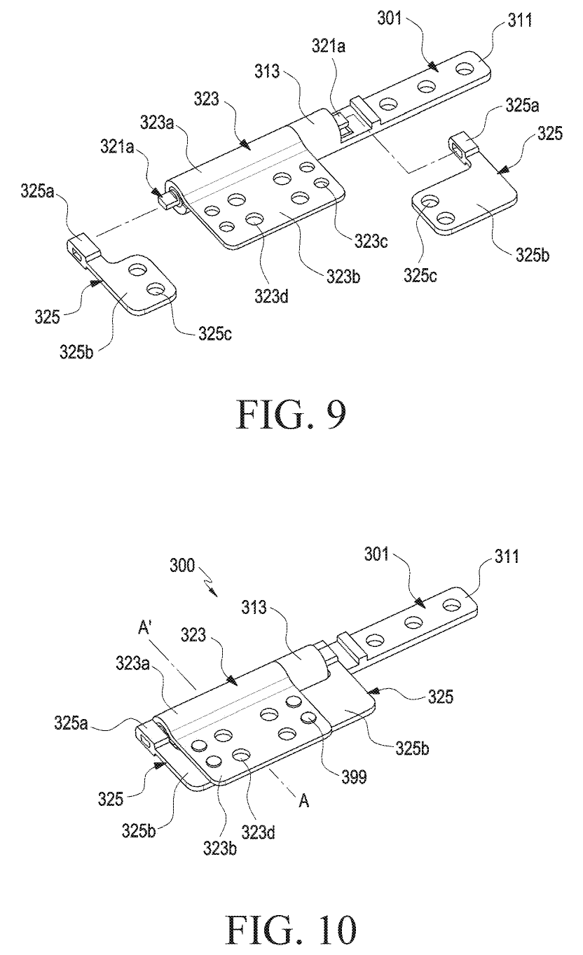

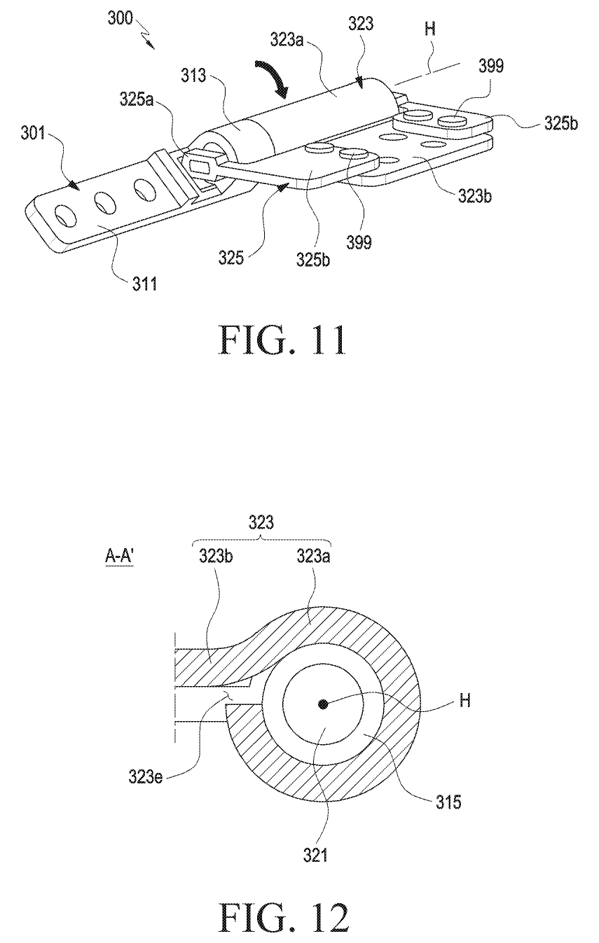

FIG. 9 is a perspective view illustrating link member(s) 325 being assembled in the hinge assembly of FIG. 6, according to an embodiment of the disclosure. FIG. 10 is a perspective view illustrating a hinge assembly according to an embodiment of the disclosure. FIG. 11 is a view illustrating the operation of a hinge assembly according to an embodiment of the disclosure.

Referring to FIGS. 9 to 11, the hinge assembly 300 when the housings 201 and 202 are in the first position facing each other (e.g., the state of FIG. 2) is illustrated in FIG. 10, and FIG. 11 illustrates the hinge assembly 300 when the housings 201 and 202 are in the second position unfolded by about 130 degrees (e.g., the state of FIG. 3).

Referring to FIGS. 9 to 11, the link member(s) 325 may be coupled to one of two opposite ends of the shaft 321 with the hub portion 325a receiving the first D-shaped plane 321d. Although not given reference numbers, the link member(s) 325 (e.g., the hub portion 325a) may include a binding hole having a shape corresponding to the end shape of the shaft 321 (e.g., the first D-shaped plane 321a). For example, when the shaft 321 rotates, the link member(s) 325 may rotate (or pivot) with respect to the hollow shaft 315 together with the shaft 321.

When the second fixing plate 325b is aligned at a position facing and/or in direct contact with the first fixing plate 323b, a fastening member 399 (e.g., rivet) may be bound to the first fastening hole 323c and the third fastening hole 325c. For example, the link member(s) 325 may connect the shaft 321 and the bracket 323 so that when one of the shaft 321 and the bracket 323 rotates, the other one of the shaft 321 and the bracket 323 may be rotated. In the illustrated embodiment, by providing link members 325 at two opposite ends of the shaft 321, respectively, the interlocking structure of the shaft 321 and the bracket 323 may be further stabilized.

Friction force may be generated substantially simultaneously on the inner circumferential surface and outer circumferential surface of the hollow shaft 315. Such friction force may maintain the housings 201 and 202 in a stopped state at an angular position according to user requirements. When implemented in the same size, the hinge assembly 300 may provide a larger static friction force by implementing a wide area capable of generating friction force. The hinge assembly 300 may be downsized when providing the same static friction force. For example, the hinge assembly 300 may stably maintain the stopped state of the housings 201, 202 at an angular position according to user requirements by providing sufficient contact area between the hollow shaft 315 and the shaft 321 and/or between the hollow shaft 315 and the bracket 323 (e.g., the sleeve 323a) while being downsized.

FIG. 12 is a view illustrating a portion of a hinge assembly (e.g., the hinge assemblies of FIGS. 3 to 6), sectioned along line A-A' of FIG. 10, according to an embodiment of the disclosure.

Referring to FIG. 12, when manufacturing the bracket 323 (e.g., the sleeve 323a and/or first fixing plate 323b) by rolling a portion of the edge of a plate member, a first slit 323e may be formed between the sleeve 323a and the first fixing plate 323b. For example, a designated gap may be provided between an end of the sleeve 323a and another portion of the sleeve 323a (or a portion of the surface of the first fixing plate 323b) to implement the first slit 323e. In an initially manufactured state and/or pre-assembly state, the inner diameter of the sleeve 323a may be smaller than the outer diameter of the hollow shaft 315 and, when deformed by external force, the sleeve 323a may accumulate elastic restoring force.

When coupled to surround the hollow shaft 315, the sleeve 323a may accumulate elastic force as the first slit 323e is deformed to extend somewhat. The elastic force accumulated in the sleeve 323a may substantially act as a force that presses the sleeve 323a against the outer circumferential surface of the hollow shaft 315. For example, the first slit 323e may provide a condition that allows the hinge assembly 300 to generate greater static friction force between the hollow shaft 315 and the bracket 323 (e.g., the sleeve 323a).

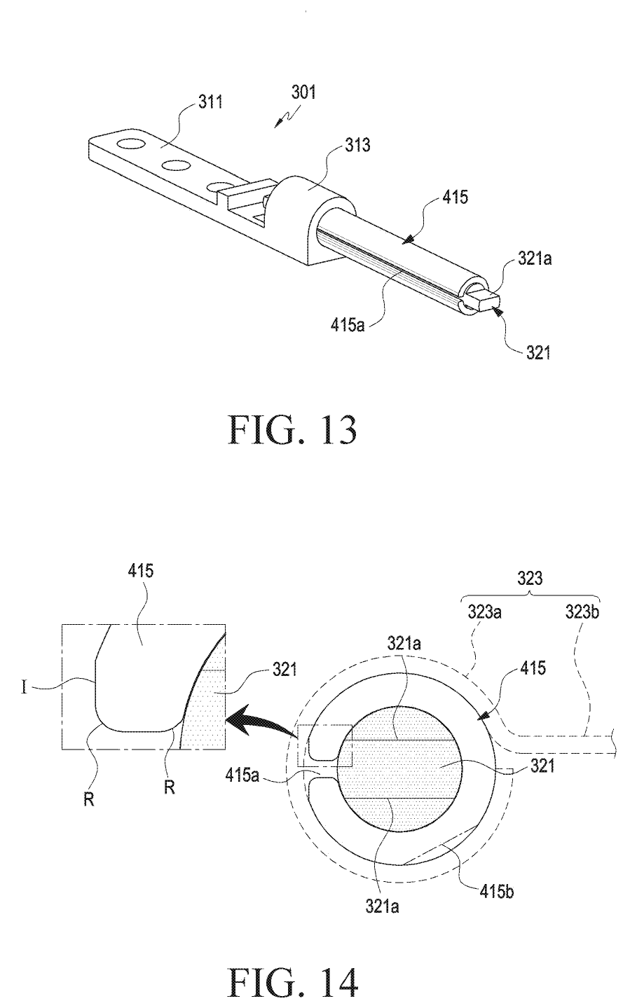

Similar to this first slit 323e, the hollow shaft 315 may include a second slit (e.g., the second slit 415a of FIGS. 13 and 14). The embodiment of such a hollow shaft is examined with reference to FIGS. 13 and 14.

FIG. 13 is a perspective view illustrating a fixing member and/or shaft of a hinge assembly (e.g., the hinge assemblies of FIGS. 3 to 6) according to an embodiment of the disclosure. FIG. 14 is a view illustrating a state in which the shaft is assembled to the fixing member of a hinge assembly according to an embodiment of the disclosure.

Referring to FIGS. 13 and 14, the hollow shaft 415 of the fixing member 301 may include a second slit 415a extending along the length direction and, when deformed by external force, the second slit 415a may extend or contract to accumulate elastic restoring force. In an initially manufactured state or pre-assembly state, the inner diameter of the hollow shaft 415 may be smaller than the outer diameter of the shaft 321. For example, when coupled to surround the shaft 321, the hollow shaft 415 may accumulate elastic force as the second slit 415a extends somewhat. The elastic force accumulated in the hollow shaft 415 may substantially act as a force that presses the hollow shaft 415 against the outer circumferential surface of the shaft 321. For example, the second slit 415a may provide a condition that may generate greater static friction force between the shaft 321 and the hollow shaft 415.

The hollow shaft 415 may be manufactured as a single piece body with the third fixing plate 311 and/or the fixing boss 313. The hollow shaft 415 may be manufactured separately from the third fixing plate 311 and/or the fixing boss 313 and may be coupled to the fixing boss 313 in a separate assembly process. In a structure coupled to the fixing boss in a separate assembly process, the hollow shaft 415 may further include a second D-shaped plane 415b provided at one end (e.g., the portion indicated as '315a' in FIG. 7). By including the second D-shaped plane 415b, the hollow shaft 415 may be constrained from rotating on the third fixing plate 311 and/or fixing boss 313. For example, in the operation of folding or unfolding the housings 201 and 202, the rotating member 302 (e.g., the shaft 321, bracket (e.g., the bracket 323 of FIG. 6) and/or link member(s) (e.g., the link member 325 of FIG. 6)) rotates with respect to the hollow shaft 415, providing static friction force on the inner circumferential surface and outer circumferential surface of the hollow shaft 415 to maintain the folded state (or inclinedly unfolded state with respect to each other) of the housings 201 and 202 according to user requirements. Such a shape of the hollow shaft 415, e.g., the second D-shaped plane 415b, may also be provided in the embodiment of the hollow shaft 315 of FIG. 6.

As the second slit 415a is formed, edges of acute, obtuse, and/or right angles may be created between the inner wall of the second slit 415a and the outer circumferential surface (or inner circumferential surface) of the hollow shaft 415. Such edges may cause damage such as scratches to the inner circumferential surface of the sleeve 323a or the outer circumferential surface of the shaft 321 during assembly or rotation operation. The edge portion(s) of the hollow shaft 415 due to the formation of the second slit 415a and/or the surrounding area may suppress damage due to friction or interference between different portions (e.g., the hollow shaft 415 and sleeve 323a, or hollow shaft 415 and shaft 321) during the assembly process or operation of the hinge assembly 203, 300 through processing such as inclined surface treatment (I) or curved surface treatment (R).

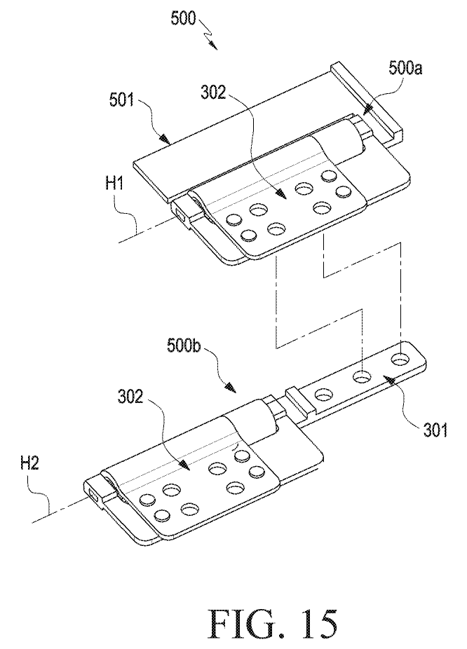

FIG. 15 is a perspective view illustrating a hinge assembly (e.g., the hinge assemblies of FIGS. 3 to 6) according to an embodiment of the disclosure.

Referring to FIG. 15, the hinge assembly 500 may include a first hinge assembly 500a and a second hinge assembly 500b connected (or coupled) in parallel. Although not illustrated, the hinge assembly 500 may further include a third hinge assembly connected in parallel to the rotating member 302 of the second hinge assembly 500b, and/or a fourth hinge assembly connected in parallel to the rotating member of the third hinge assembly. For example, the hinge assembly 500 of FIG. 15 may be implemented by connecting the above-described hinge assemblies (e.g., the hinge assembly 300 of FIGS. 3 to 14) in parallel. The structure of the first hinge assembly 500a and/or the structure of the second hinge assembly 500b may be substantially the same as the hinge assembly 300 examined with reference to FIGS. 3 to 14.

The shape of the fixing member 301 or 501 or rotating member 302 may be appropriately modified according to the specifications of the electronic device (e.g., the electronic device 101, 102, 104, or 200 of FIGS. 1 to 5) and/or hinge assembly 203, 300, or 500. For example, the fixing member 501 of the first hinge assembly 500a may have a plate shape disposed alongside one side of the rotating member 302. For example, the hinge arm 213 of FIG. 3 and/or the hinge portion 223 of FIG. 3 may be omitted, and a portion of the fixing member 501 of the first hinge assembly 500a may be fixed inside one of the first housing 201 and the second housing 202. In this case, a portion of the rotating member 302 of the second hinge assembly 500b may be fixed inside the other one of the first housing 201 and the second housing 202. When including such a hinge assembly 500, the hinge arm 213 and/or the hinge portion 223 of FIG. 3 are omitted, and the first housing 201 and the second housing 202 may be substantially rectangular or cuboid in shape. However, the embodiment of the disclosure is not limited thereto, and some of the surfaces of the first housing 201 and the second housing 202 may include curved or inclined surfaces.

The first hinge assembly 500a may provide a first hinge axis H1, and the second hinge assembly 500b may provide a second hinge axis H2 disposed at a designated distance from the first hinge axis H1. The first hinge axis H1 and the second hinge axis H2 may be substantially parallel. Each of the hollow shaft of the first hinge assembly 500a (e.g., the hollow shaft 315 of FIG. 6) and/or the hollow shaft of the second hinge assembly 500b (e.g., the hollow shaft 315 of FIG. 6) may generate static friction force that supports or maintains the housings 201 and 202 in a state required by the user. When the hinge arm 213 and/or the hinge portion 223 of FIG. 3 are omitted so that the first housing 201 and the second housing 202 have a substantially rectangular or cuboid shape, and/or when a portion of the fixing member 501 of the first hinge assembly 500a and a portion of the rotating member 302 of the second hinge assembly 500b are fixed inside one of the housings 201 and 202, the first hinge axis H1 and the second hinge axis H2 may be disposed in the area of the first housing 201 and the second housing 202. For example, when defining that the hinge axis H of FIG. 2 or 3 passes through a portion of the first housing 201 on the hinge arm 213 and passes through a portion of the second housing 202 on the hinge portion 223, in an electronic device including the hinge assembly 500 of FIG. 15, the hinge axes H1, H2 may be understood as being positioned outside the housings (e.g., the housings 201, 202 of FIG. 2 or 3).

The display 221 may be extended to reach the area where the input devices 211a and 211b of the first housing 201 of FIG. 3 are disposed, and the display 221 may replace the input devices 211a and 211b of FIG. 3 by including a touchscreen function at least in the area corresponding to the first housing 201. For example, the electronic device 200 may include a flexible display disposed from the first housing 201 to the second housing 202. In this case, when the housings 201 and 202 are folded, a portion of the display 221 adjacent to the hinge arm(s) 213 and/or hinge portion 223 may be deformed into a shape having a considerably large curvature (e.g., a radius of curvature within about 1mm). When the display 221 is structured to be deformed into a shape having a considerably large curvature, the internal structure of the display 221 (e.g., pixel(s), arrangement of pixels, and/or various electrical lines) may be damaged by the deformation of the display 221. The hinge assembly 500 of FIG. 15 may maintain the curvature of the display 221 within a designated range (e.g., a radius of curvature of about 2mm or more) even when the housings 201, 202 are folded by having the first hinge axis H1 and the second hinge axis H2 disposed at a designated interval.

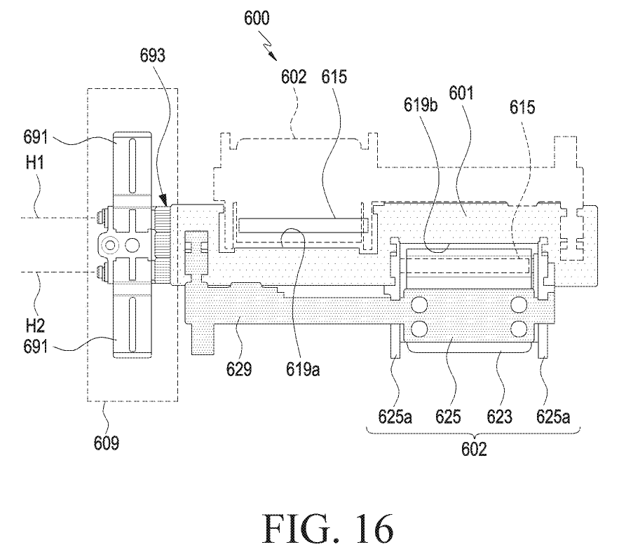

FIG. 16 is a perspective view illustrating a hinge assembly (e.g., the hinge assemblies of FIGS. 3 to 6 or 15) according to an embodiment of the disclosure.

Referring to FIG. 16, the hinge assembly 600 may be similar to the hinge assembly 500 of FIG. 15 in that the hinge assembly 600 provides a first hinge axis H1 and a second hinge axis H2 disposed substantially parallel at a designated interval. However, the hinge assembly 600 of FIG. 16 may differ from the hinge assembly 500 in having a configuration including a plurality of rotating members 602 rotatably coupled to one fixing member 601.

The fixing member 601 may be in a plate shape extending along the direction of the hinge axes H1, H2 and may provide accommodation spaces 619a and 619b extending inward from different sides (or edges). The fixing member 601 may include hollow shafts 615 (e.g., the hollow shaft 315 of FIG. 6 or 7) disposed in the accommodation spaces 619a. One of the hollow shafts 615 may be understood as being aligned with the first hinge axis H1, and another one of the hollow shafts 615 may be understood as being aligned with the second hinge axis H2. The shape or structure of the hollow shaft 615 may be similar to the above-described embodiment. In an embodiment, one end of the hollow shaft 615 may be fixed to the inner wall of the accommodation space 619a, and the other end may be disposed to be spaced apart from the inner wall of the accommodation space 619a. In an embodiment, when both inner walls of the accommodation space 619a have a structure similar to the fixing boss 313 of FIG. 7, two opposite ends of the hollow shaft 615 may have a structure fixed to both inner walls of the accommodation space 619a.

Although not illustrated, similar to FIGS. 6 or 8, a shaft (shaft 321 of FIG. 6 or 8) may be rotatably received in the hollow shaft 615. In the state received in the hollow shaft 615, one end of the shaft (e.g., the first D-shaped plane 321a of FIG. 8) may be exposed at the end of the hollow shaft 615. For example, in a structure in which one end of the hollow shaft 615 is disposed to be spaced apart from the inner wall of the accommodation space 619a, one end of the shaft (e.g., the first D-shaped plane 321a of FIG. 8) may be positioned in the accommodation space 619a while being exposed at the end of the hollow shaft 615. When the fixing member 601 has a structure similar to the fixing boss 313 of FIG. 7, two opposite ends of the hollow shaft 615 are fixed to the inner walls of the accommodation space 619a, and two opposite ends of the shaft may be positioned on the fixing member 601 while being disposed outside the accommodation space 619a.

The rotating member(s) 602 may include a bracket 623 (e.g., the bracket 323 of FIG. 6) and a link member 625 (e.g., the link member 325 of FIG. 6). For example, similar to the embodiment of FIG. 6, the bracket 623 may be coupled to surround the hollow shaft 615 in a state rotatable about the hollow shaft 615, and the link member 625 may be fixed to the bracket 623 while being fixed to the shaft through the hub portion 625a. For example, the shaft and the bracket 623 may rotate substantially simultaneously with respect to the hollow shaft 615 by being connected through the link member 625 (and/or hub portion 625a). In an embodiment, when defining that the fixing member 601 is fixed on the hinge axes H1, H2, the rotating member(s) 602 may be understood as rotating around one of the hinge axes H1, H2.

The hinge assembly 600 and/or rotating member(s) 602 may further include fixing piece(s) 629. The fixing piece 629 may be understood as, e.g., extending from the bracket 623 or link member 625 and disposed alongside the hinge axes H1, H2. When the hinge assembly 600 connects or couples the housings (e.g., the housings 201 and 202 of FIGS. 2 or 3), at least a portion of the bracket 623, link member 625, and/or fixing piece 629 may be received (or fixed) in one of the housings 201, 202. For example, in FIG. 16, when the rotating member 602 illustrated with dashed lines is at least partially received (or fixed) in the first housing 201, the rotating member 602 illustrated with solid lines may be at least partially received in the second housing 202. When the rotating member 602 is received or fixed in one of the housings 201 and 202, the fixing piece 629 may provide a stable binding or fixing structure.

The hinge assembly 600 may further include an interlocking hinge module 609. The interlocking hinge module 609 may include a first coupling piece 691 that pivots (or rotates) around the first hinge axis H1, a second coupling piece that pivots (or rotates) around the second hinge axis H2, and/or a gear module 693. The first coupling piece 691 may be fixed to, e.g., the first housing 201 of FIGS. 2 or 3, and the second coupling piece may be fixed to the second housing 202 of FIGS. 2 or 3. The gear module 693 may include at least one pair of sun gears meshed with each other, where one of the sun gears rotates according to the pivoting of the first coupling piece 691, and another one of the sun gears may rotate according to the pivoting of the second coupling piece.

Since the sun gears are in a meshed state, when the first coupling piece 691 pivots, the second coupling piece may pivot by the sun gears. When the first housing 201 pivots in a direction facing the second housing 202 (e.g., folding direction), the second housing 202 may pivot in a direction folding toward the first housing 201 by such an interlocking hinge module 609 (e.g., the gear module 693). In the illustrated embodiment, a configuration is illustrated where the interlocking hinge module 609 is disposed on (or coupled to) one side of the fixing member 601, but it should be noted that the embodiment(s) of the disclosure are not limited thereto. The interlocking hinge module 609 may be disposed at a position separated by a designated distance from the fixing member 601. For example, the interlocking hinge module 609 may be disposed at a position separated by a designated distance from the fixing member 601 by moving to the left along the direction of the first hinge axis H1 or second hinge axis H2 from the state illustrated in FIG. 16.

In implementing the hinge assembly 600 including the hollow shaft 615, rotating members 602 that rotate around different hinge axes H1, H2 may be provided on one fixing member 601. The display 221 may be extended to reach the area where the input devices 211a and 211b of the first housing 201 of FIG. 3 are disposed, and in the portion (or area) adjacent to the hinge assembly 600, the display 221 may be deformed between a curved form and a flat form. As examined with reference to FIG. 15, in an electronic device including such an extended display structure, the hinge assembly 600 providing a plurality of different hinge axes H1, H2 may facilitate the deformation of the display while suppressing or mitigating damage to the display.

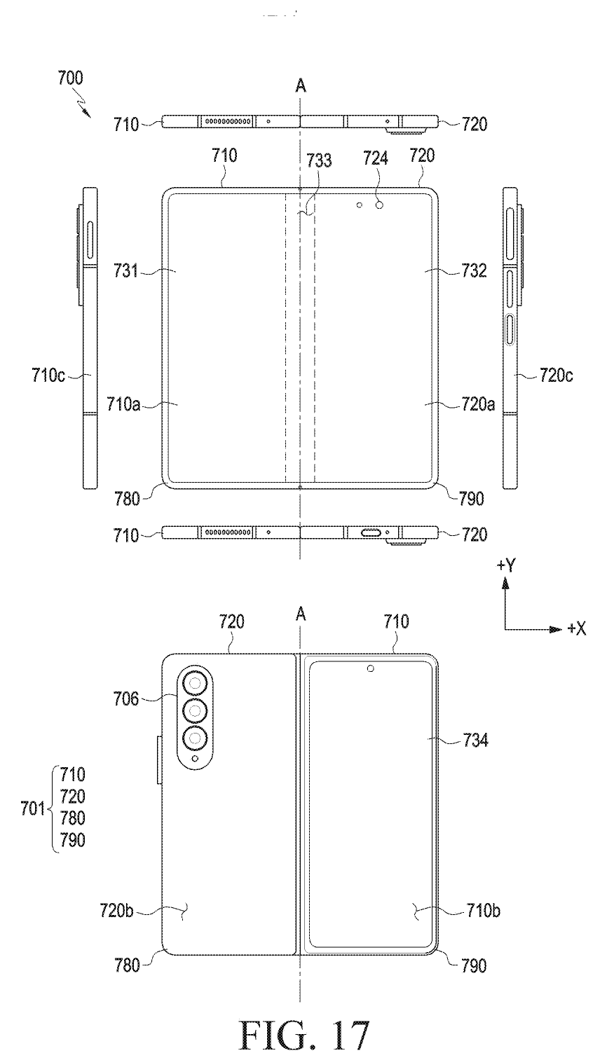

An electronic device including the hinge assembly 500 or 600 of FIG. 15 or 16 is examined with reference to FIGS. 17 to 19. In the embodiments described below, a plurality of housings may be rotatably coupled to be rotatable relative to each other between a first position in which they are folded to face each other and a second position in which they are unfolded side by side. The following description with reference to the Cartesian coordinate system may focus primarily on the unfolded state. In the electronic device according to the embodiments described below, the folding axis(es) may be understood as substantially parallel to the Y-axis direction. However, embodiment(s) of the disclosure are not limited thereto, and embodiment(s) of the disclosure may be understood as including electronic devices having a structure in which the folding axis(es) is parallel to the X-axis direction.

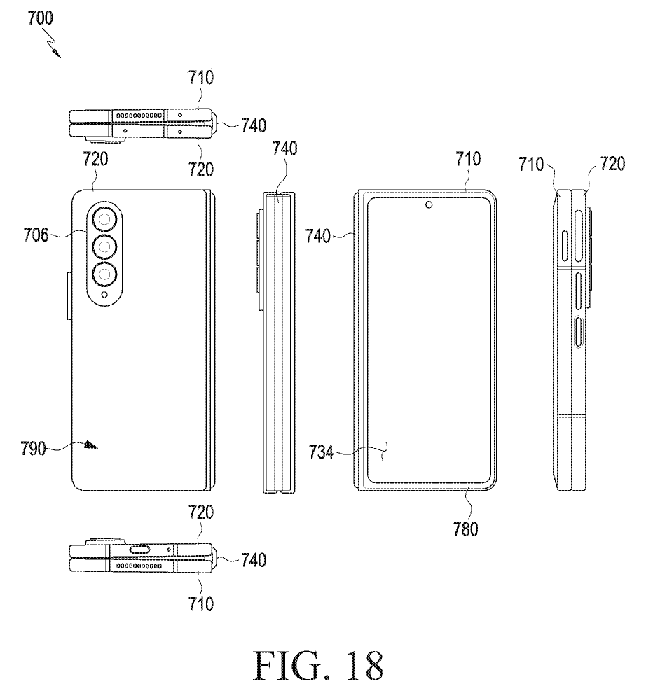

FIG. 17 is a view illustrating an unfolded state of an electronic device according to an embodiment of the disclosure. FIG. 18 is a view illustrating a folded state of an electronic device according to an embodiment of the disclosure.

Referring to FIGS. 17 and 18, an electronic device 700 may include a housing 701, a hinge cover 740 covering a foldable portion of the housing 701, and a display 730 disposed in a space formed by the housing 701. The surface where the screen output from the display 730 is exposed may be defined as a front surface (e.g., the first front surface 710a and the second front surface 720a) of the electronic device 700. A surface opposite to the front surface may be defined as a rear surface (e.g., the first rear surface 710b and the second rear surface 720b) of the electronic device 700. A surface surrounding the space between the front surface and the rear surface may be defined as a side surface (e.g., the first side surface 710c and the second side surface 720c) of the electronic device 700. The side surface of the electronic device 700 may be a side surface of at least one of the first housing 710 or the second housing 720. The electronic device 700 of FIGS. 17 and 18 may be referred to as a foldable electronic device, a portable electronic device, or a portable foldable electronic device. The housing 701 may be referred to as a foldable housing. The display 730 may be referred to as a “flexible display.”

The housing 701 may include a first housing 710, a second housing 720 rotatable with respect to the first housing 710, a first rear cover 780, and a second rear cover 790. The housing 701 of the electronic device 700 is not limited to the shape and coupling shown in FIGS. 17 and 18 but may rather be implemented in other shapes or via a combination and/or coupling of other components. For example, in an embodiment, the first housing 710 and the first rear cover 780 may be integrally formed with each other, and the second housing 720 and the second rear cover 790 may be integrally formed with each other.

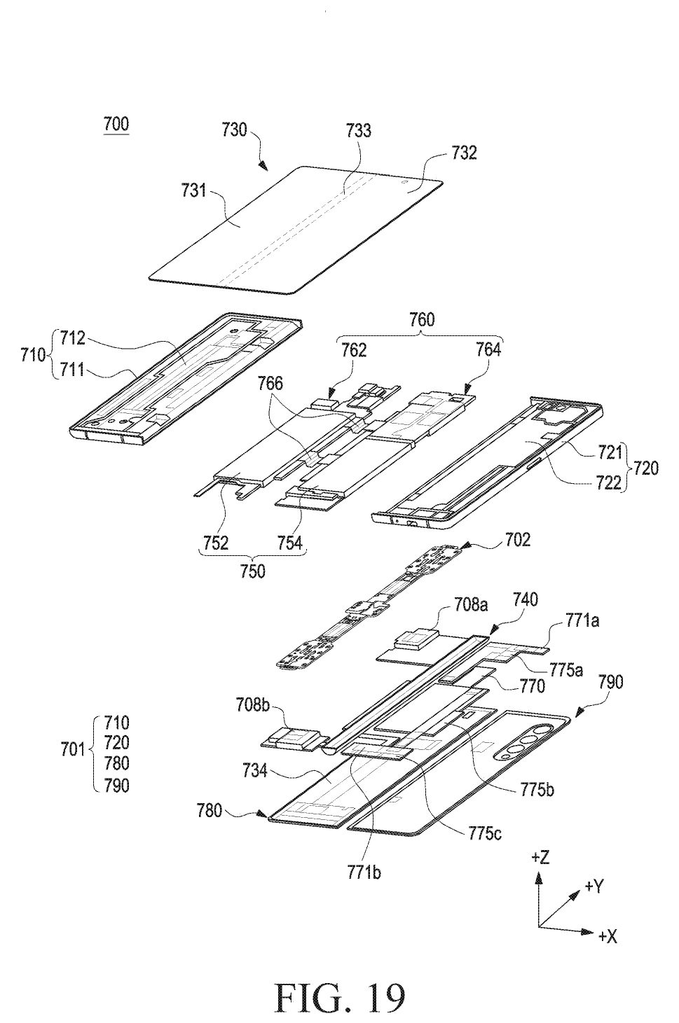

The first housing 710 may be connected to a hinge structure (e.g., the hinge assembly 600 of FIG. 16 and/or the hinge assembly 702 of FIG. 19) and may include a first front surface 710a facing in a first direction and a first rear surface 710b facing in a second direction opposite to the first direction. The second housing 720 may be connected to the hinge assembly 702 and may include a second front surface 720a facing in a third direction and a second rear surface 720b facing in a fourth direction opposite to the third direction, and may rotate from the first housing 710 about the hinge assembly 702. Accordingly, the electronic device 700 may be changed to a folded state or an unfolded state. In the folded state of the electronic device 700, the first front surface 710a may face the second front surface 720a and, in the unfolded state, the third direction may be identical to the first direction. Hereinafter, unless otherwise mentioned, directions are described based on the unfolded state of the electronic device 700.

The first housing 710 and the second housing 720 may be disposed on both sides of the folding axis A and be overall symmetrical in shape with respect to the folding axis A. As set forth below, the first housing 710 and the second housing 720 may have different angles or distances formed therebetween depending on whether the electronic device 700 is in the unfolded, folded, or intermediate state. The second housing 720 may further includes the sensor area 724 where sensors (e.g., front camera) are disposed but, in the remaining area, the second housing 720 may be symmetrical in shape with the first housing 710.

The folding axis A (e.g., the hinge axes H1, H2 of FIG. 16) may be a plurality (e.g., two) of parallel folding axes. In the disclosure, the folding axis A is provided along the length direction (Y-axis direction) of the electronic device 700, but the direction of the folding axis A is not limited thereto. For example (not shown), the electronic device 700 may include the folding axis extending along the width direction (e.g., X-axis direction).

The electronic device 700 may include a structure to which a digital pen (not shown) may be attached. For example, the electronic device 700 may include a magnetic substance configured to attach the digital pen to a side surface of the first housing 710 or a side surface of the second housing 720. According to an embodiment, the electronic device 700 may include a structure into which a digital pen may be inserted. For example, a hole (not shown) into which the digital pen may be inserted may be formed in a side surface of the first housing 710 or a side surface of the second housing 720 of the electronic device 700.

The first housing 710 and the second housing 720 may at least partially be formed of a metal or non-metallic material with a rigidity selected to support the display 730. At least a portion formed of metal may provide a ground plane of the electronic device 700 and may be electrically connected with a ground line formed on a printed circuit board (e.g., the board unit 760 of FIG. 19).

The sensor area 724 may be formed adjacent to an edge or corner of the second housing 720 and to have a predetermined area. However, the placement, shape, or size of the sensor area 724 is not limited to those illustrated. For example, in another embodiment, the sensor area 724 may be provided in a different corner of the second housing 720 or in any area between the top corner and the bottom corner or in the first housing 710. Components for performing various functions, embedded in the electronic device 700, may be exposed through the sensor area 724 or one or more openings in the sensor area 724 to the front surface of the electronic device 700. In an embodiment, the components may include various kinds of sensors. The sensor(s) may include, e.g., at least one of a front camera, a receiver, or a proximity sensor.

The first rear cover 780 may be disposed on one side of the folding axis A on the rear surface of the electronic device 700 and have, e.g., a substantially rectangular periphery which may be surrounded by another structure of the first housing 710. Similarly, the second rear cover 790 may be disposed on the opposite side of the folding axis A on the rear surface of the electronic device 700 and its periphery may be surrounded by another structure of the second housing 720.

The first rear cover 780 and/or the second rear cover 790 may be substantially symmetrical in shape with respect to the folding axis (axis A). However, the first rear cover 780 and the second rear cover 790 are not necessarily symmetrical in shape. The electronic device 700 may include the first rear cover 780 and the second rear cover 790 in different shapes, not symmetrical.

The first rear cover 780, the second rear cover 790, the first housing 710, and the second housing 720 may provide a space where various components (e.g., a printed circuit board or battery) of the electronic device 700 may be disposed. One or more components may be disposed or visually exposed on the rear surface of the electronic device 700. For example, at least a portion of a sub display 734 may be visually exposed through at least a portion of the first rear cover 780. One or more components or sensors may be visually exposed through at least a portion of the second rear cover 790. According to various embodiments, the sensor may include a proximity sensor and/or a camera module 706 (e.g., rear camera).

A front camera exposed to the front surface of the electronic device 700 through one or more openings provided in the sensor area 724 or the camera module 706 exposed through at least a portion of the second rear cover 790 may include one or more lenses, an image sensor, and/or an image signal processor. Seven or more lenses (an infrared (IR) camera, a wide-angle lens, and a telephoto lens) and image sensors may be disposed on one surface of the electronic device 700.

The hinge cover 740 may be disposed between the first housing 710 and the second housing 720 to hide the internal components (e.g., the hinge assembly 600 of FIG. 16 or the hinge assembly 702 of FIG. 19). The hinge cover 740 may be hidden by a portion of the first housing 710 and second housing 720 or be exposed to the outside depending on the state (e.g., the unfolded state (e.g., flat state) or folded state) of the electronic device 700.

According to the embodiment shown in FIG. 17, in the unfolded state of the electronic device 700, the hinge cover 740 may be hidden, and thus not exposed, by the first housing 710 and the second housing 720. As another example, as shown in FIG. 18, in the folded state (e.g., a fully folded state) of the electronic device 700, the hinge cover 740 may be exposed to the outside between the first housing 710 and the second housing 720. As another example, in an intermediate state in which the first housing 710 and the second housing 720 are folded with a certain angle, the hinge cover 740 may be partially exposed to the outside between the first housing 710 and the second housing 720. However, in this case, the exposed area may be smaller than that in the completely folded state. In an embodiment, the hinge cover 740 may include a curved surface.

The display 730 may be disposed in a space formed (or defined) by the housing 701. For example, the display 730 may be seated on a recess provided by the housing 701 and may form most of the front surface of the electronic device 700. Thus, the front surface of the electronic device 700 may include the display 730 and a partial area of the first housing 710 and a partial area of the second housing 720, which are adjacent to the display 730. The rear surface of the electronic device 700 may include a first rear cover 780, a partial area of the first housing 710 adjacent to the first rear cover 780, a second rear cover 790, and a partial area of the second housing 720 adjacent to the second rear cover 790.

The display 730 may include a plurality of display areas spaced apart from each other. For example, the display 730 may include a first display area 731 disposed on the first housing 710, a second display area 732 disposed on the second housing 720, and a folding area 733. The first display area 731 and the second display area 732 may rotate about the folding axis A.

The display 730 may be a display at least a portion of which may be transformed into a flat or curved surface. For example, the display 730 may be a foldable or flexible display. In this case, the display 730 may include a folding area 733, a first display area 731 disposed on one side of the folding area 733 (e.g., the left side of the folding area 733 of FIG. 17), and a second display area 732 disposed on the opposite side of the folding area 733 (e.g., the right side of the folding area 733 of FIG. 17). However, the segmentation of the display 730 is merely an example, and the display 730 may be divided into a plurality of (e.g., four or more, or two) areas depending on the structure or function of the display 730. For example, in the embodiment illustrated in FIG. 17, the display 730 may be divided into the areas by the folding area 733 or folding axis A extending in parallel with the Y axis but, in another embodiment, the display 730 may be divided into the areas with respect to another folding area (e.g., a folding area parallel with the X axis) or another folding axis (e.g., a folding axis parallel with the X axis). The display 730 may be coupled with or disposed adjacent to a touch detection circuit, a pressure sensor capable of measuring the strength (pressure) of touches, and/or a digitizer (not shown) for detecting a magnetic field-type stylus pen.

The first display area 731 and the second display area 732 may be overall symmetrical in shape with respect to the folding area 733. Unlike the first display area 731, the second display area 732 may include a notch (not shown) depending on the presence of the sensor area 724, but the rest may be substantially symmetrical in shape with the first display area 731. For example, the first display area 731 and the second display area 732 may include symmetrical portions and asymmetrical portions.

Described below are the operation of the first housing 710 and the second housing 720 and each area of the display 730 depending on the state (e.g., the unfolded state (or flat state) and folded state) of the electronic device 700.

When the electronic device 700 is in the unfolded state (flat state) (e.g., FIG. 17), the first housing 710 and the second housing 720 may be disposed to face in the same direction while being angled substantially at 180 degrees therebetween. The surface of the first display area 731 and the surface of the second display area 732 of the display 730 may be angled at 180 degrees therebetween while facing in the same direction (e.g., forward of the front surface of the electronic device). The folding area 733 may form the same plane with the first display area 731 and the second display area 732.

When the electronic device 700 is in the folded state (e.g., FIG. 18), the first housing 710 and the second housing 720 may be disposed to face each other. The surface of the first display area 731 and the surface of the second display area 732 of the display 730 may be angled at a small angle (e.g., an angle between about 0 degrees and about 10 degrees) therefrom while facing each other. In the folded state of the electronic device 700, at least a portion of the folding area 733 may be formed as a curved surface having a predetermined curvature.

When the electronic device 700 is in the intermediate state (not shown), the first housing 710 and the second housing 720 may be disposed at a certain angle therebetween. The surface of the first display area 731 of the display 730 and the surface of the second display area 732 may form an angle which is larger than the angle in the folded state and smaller than the angle in the unfolded state. The folding area 733 may at least partially have a curved surface with a predetermined curvature and, in this case, the curvature may be smaller than that when it is in the folded state.

FIG. 19 is an exploded perspective view illustrating an electronic device according to an embodiment of the disclosure.

Referring to FIG. 19, an electronic device 700 (e.g., the electronic device 101 of FIG. 1) may include a housing 701, a display 730, a hinge assembly 702, a battery 750, and a board unit 760. For example, the housing 701 may include a first housing 710, a second housing 720, a first rear cover 780, and a second rear cover 790. The configuration of the first housing 710, the second housing 720, the hinge cover 740, the first rear cover 780, and the second rear cover 790 of FIG. 19 may be identical in whole or part to the configuration of the first housing 710, the second housing 720, the hinge cover 740, the first rear cover 780, and the second rear cover 790 of FIG. 17 and/or FIG. 18.

The first housing 710 and the second housing 720 may be assembled together to be coupled to two opposite sides of the hinge assembly 702. For example, the hinge assembly 702 may be disposed in a hinge area between the first housing 710 and the second housing 720 to rotatably couple the first housing 710 and the second housing 720. Here, the ‘hinge area’ may refer to a space where the hinge assembly 702 is disposed, an area at least partially surrounded by the hinge cover 740, and/or a space between the hinge cover 740 and the folding area 733 of the display 730. The hinge area may be understood as a space disposed substantially corresponding to the folding area 733.

The first housing 710 may include a first supporting area 712 (e.g., a first supporting member) that may support the components (e.g., the first circuit board 762 and/or the first battery 752) of the electronic device 700 and a first sidewall 711 surrounding at least a portion of the first supporting area 712. The first sidewall 711 may include a first side surface (e.g., the first side surface 710c of FIG. 17) of the electronic device 700. The second housing 720 may include a second supporting area 722 that may support the components (e.g., the second circuit board 764 and/or the second battery 754) of the electronic device 700 and a second sidewall 721 surrounding at least a portion of the second supporting area 722. The second sidewall 721 may include a second side surface (e.g., the second side surface 720c of FIG. 17) of the electronic device 700.

Although not shown, the first housing 710 may include a first waterproofing member disposed in the first supporting area 712 and/or the second housing 720 may include a second waterproofing member disposed in the second supporting area 722. The first waterproofing member and/or the second waterproofing member may be disposed in the gaps between the display 730 and the supporting area(s) 712 and 722 to suppress influx of moisture or foreign bodies from the outside to the inside of the first housing 710 and/or the second housing 720.

The display 730 may include a first display area 731, a second display area 732, and/or a folding area 733. The configuration of the first display area 731, the second display area 732, and the folding area 733 of FIG. 19 may be identical in whole or part to the configuration of the first display area 731, the second display area 732, and the folding area 733 of FIG. 17.

The electronic device 700 may further include a sub display 734. The sub display 734 may display screen in a different direction from the display areas 731 and 732. For example, the sub display 734 may output screen in a direction opposite to the first display area 731. According to an embodiment, the sub display 734 may be disposed on the first rear cover 780.

The battery 750 may include a first battery 752 disposed in the first housing 710 and a second battery 754 disposed in the second housing 720. According to an embodiment, the first battery 752 may be connected with the first circuit board 762, and the second battery 754 may be connected to the second circuit board 764. The battery 750 may supply power to at least one component of the electronic device 700. The battery 750 may include, e.g., a non-rechargeable primary battery, a rechargeable secondary battery, or a fuel cell.

The board unit 760 may include a first circuit board 762 disposed in the first housing 710 and a second circuit board 764 disposed in the second housing 720. The first circuit board 762 and the second circuit board 764 may be electrically connected by at least one flexible printed circuit board 766. At least a portion of the flexible printed circuit board 766 may be disposed across the hinge area or hinge structure (e.g., the hinge assembly 702). The first circuit board 762 and the second circuit board 764 may be disposed in a space formed by the first housing 710, the second housing 720, the first rear cover 780, and the second rear cover 790. Components for implementing various functions of the electronic device 700 may be disposed on the first circuit board 762 and the second circuit board 764.

The electronic device 700 may include speakers 708a and 708b. The speakers 708a and 708b may convert electrical signals into sound. The speakers 708a and 708b may be disposed inside a space formed by the first housing 710, the second housing 720, the first rear cover 780, and the second rear cover 790. The speakers 708a and 708b may include an upper speaker 708a positioned at the upper portion (+Y direction) of the electronic device 700 and a lower speaker 708b positioned at the lower portion (-Y direction) of the electronic device 700. In the disclosure, the speakers 708a and 708b are illustrated as being positioned within one housing (e.g., the first housing 710 of FIG. 19), but this is an optional structure. For example, the speakers 708a and 708b may be positioned within at least one of the first housing 710 or the second housing 720. The configuration of the speakers 708a and 708b of FIG. 19 may be the same as all or some of the configuration of the audio output module 155 of FIG. 1.

The electronic device 700 may include a rear member 770 (or rear case). The rear member 770 may be disposed in the housing 701 (e.g., the second housing 720). The rear member 770 may accommodate at least one antenna.

The electronic device 700 may include an antenna. The antennas 775a and 775b may include, e.g., an ultra-wide band (UWB) antenna 775a, a near-field communication (NFC) antenna, a wireless charging antenna, and/or a magnetic secure transmission (MST) antenna 775b. The antenna 775 may perform short-range communication with, e.g., an external device or may wirelessly transmit or receive power necessary for charging.

An antenna structure may be formed by a portion of the housing 701 or a combination thereof. For example, the antenna may include a communication antenna 775c at least a portion of which is exposed to the outside and which forms at least a portion of the exterior of the electronic device 700. The communication antenna 775c may be used for communication (e.g., Wi-Fi) with an external electronic device. For example, the communication antenna 775c may be positioned at the upper portion 771a or lower portion 771b of the rear member 770.

In the above-described embodiment, a configuration in which a pair of housings (or housing structures) are rotatably coupled by a hinge structure (or hinge assembly) may be illustrated. However, it should be noted that such embodiments do not limit the electronic device according to the embodiment(s) disclosed in the disclosure. For example, the electronic device according to the embodiment(s) of the disclosure may include three or more housings, and the "pair of housings" in the above-described embodiment may refer to "two housings rotatably coupled to each other among three or more housings."

As described above, the hinge assembly (e.g., the hinge assemblies 203, 300, 500 of FIG. 3, FIG. 6, and/or FIG. 15) according to an embodiment of the disclosure and/or the electronic device including the same (e.g., the electronic device 101, 102, 104, 200 of FIGS. 1 to 5) may generate static friction force substantially simultaneously on the inner circumferential surface and outer circumferential surface of the hollow shaft (e.g., the hollow shaft 315, 415 of FIG. 6 or 13). For example, in rotatably coupling the housings (e.g., the first housing 201 and second housing 202 of FIG. 2 or 3), the folded state or unfolded state of the housings according to user requirements may be stably maintained. In an embodiment, by generating static friction force simultaneously on the inner circumferential surface and outer circumferential surface of the hollow shaft, the hinge assembly may provide greater static friction force even when manufactured in substantially the same size as a general hinge structure, and miniaturization of the hinge assembly may be facilitated when providing substantially the same size of static friction force.

The effects obtainable from the disclosure are not limited to the effects mentioned above, and other effects not mentioned are clearly understood by those having ordinary skill in the art to which the disclosure belongs from the description of the above-described embodiment(s).

According to an embodiment of the disclosure, a hinge assembly (e.g., the hinge assemblies 203, 300, 500 of FIG. 3, FIG. 6, and/or FIG. 15) includes a fixing member (e.g., the fixing member 301 of FIG. 6) including a hollow shaft (e.g., the hollow shaft 315, 415 of FIG. 6 or 13) extending along a direction of a hinge axis (e.g., the hinge axis H of FIG. 6), a shaft (e.g., the shaft 321 of FIG. 6) received at least partially in the hollow shaft and configured to rotate around the hinge axis within the hollow shaft, a bracket (e.g., the bracket 323 of FIG. 6) coupled to surround at least a portion of the hollow shaft and configured to rotate around the hinge axis, and at least one link member (e.g., the link member(s) 325 of FIG. 6), wherein a portion of the at least one link member is coupled to the shaft and another portion of the at least one link member is fixed to the bracket. In an embodiment, the shaft and the bracket may be configured to rotate together with respect to the hollow shaft by being connected through the at least one link member.

According to an embodiment, the shaft may be configured to rub against an inner circumferential surface of the hollow shaft, and the bracket may be configured to rub against an outer circumferential surface of the hollow shaft.

According to an embodiment, the bracket may include a sleeve (e.g., the sleeve 323a of FIG. 6) coupled to surround the outer circumferential surface of the hollow shaft and configured to rotate, and a first fixing plate (e.g., the first fixing plate 323b of FIG. 6) extending from the sleeve and configured to pivot around the hollow shaft as the sleeve rotates.

According to an embodiment, the sleeve may be configured to rub against the outer circumferential surface of the hollow shaft as the bracket rotates.

According to an embodiment, the bracket may further include at least one first fastening hole (e.g., the first fastening hole 323c of FIG. 6) provided on the first fixing plate in an area facing the link member, and at least one second fastening hole (e.g., the second fastening hole 323b of FIG. 6) disposed adjacent to the at least one first fastening hole.

According to an embodiment, the at least one link member may include a hub portion (e.g., the hub portion 325a of FIG. 6) bound or fixed to one of two opposite ends of the shaft, and a second fixing plate (e.g., the second fixing plate 325b of FIG. 6) extending from the hub portion and disposed to at least partially face the first fixing plate.

According to an embodiment, the second fixing plate may be fixed to the first fixing plate while facing the first fixing plate.

According to an embodiment, the at least one link member may further include a third fastening hole (e.g., the third fastening hole 325c of FIG. 6) provided to pass through the second fixing plate.

According to an embodiment, such a hinge assembly may further include a fastening member (e.g., the fastening member 399 of FIG. 6) fixed to the first fixing plate while passing through the third fastening hole.

According to an embodiment, the hollow shaft may include a slit (e.g., the second slit 415a of FIG. 13 or 14) extending along the direction of the hinge axis.

According to an embodiment, the fixing member may include a third fixing plate (e.g., the third fixing plate 311 of FIG. 6) extending along the direction of the hinge axis, and a fixing boss (e.g., the fixing boss 313 of FIG. 6) provided at one end of the third fixing plate. In an embodiment, the hollow shaft may be bound or fixed to the fixing boss.

According to an embodiment, one end of the shaft may protrude from one end of the hollow shaft, and the other end of the shaft may protrude from the other end of the hollow shaft and protrude to one side of the fixing boss.

According to an embodiment, the hollow shaft may include a D-shaped plane (e.g., the second D-shaped plane 415b of FIG. 14) provided on an outer circumferential surface of a portion bound to the fixing boss.

According to an embodiment of the disclosure, an electronic device (e.g., the electronic device 101, 102, 104, 200 of FIGS. 1 to 5) includes a first housing (e.g., the first housing 201 of FIG. 2 or 3), a second housing (e.g., the second housing 202 of FIG. 2 or 3) configured to pivot around a hinge axis (e.g., the hinge axis H of FIG. 2, 3 and/or 6) between a first position facing the first housing and a second position unfolded by a designated angle from the first position, and a hinge assembly (e.g., the hinge assemblies 203, 300, 500 of FIG. 3, 6 and/or 15) rotatably coupling the first housing and the second housing. In an embodiment, the hinge assembly includes a fixing member (e.g., the fixing member 301 of FIG. 6) disposed at least partially in one of the first housing and the second housing and including a hollow shaft (e.g., the hollow shaft 315, 415 of FIG. 6 or 13) extending along the direction of the hinge axis, a shaft (e.g., the shaft 321 of FIG. 6) received at least partially in the hollow shaft and configured to rotate around the hinge axis within the hollow shaft, a bracket (e.g., the bracket 323 of FIG. 6) disposed at least partially in the other one of the first housing and the second housing, coupled to surround at least a portion of the hollow shaft, and configured to rotate around the hinge axis, and at least one link member (e.g., the link member(s) 325 of FIG. 6), wherein a portion of the at least one link member is coupled to the shaft and another portion of the at least one link member is fixed to the bracket. In an embodiment, the shaft and the bracket may be configured to rotate together with respect to the hollow shaft by being connected through the at least one link member.

According to an embodiment, such an electronic device may further include an input device (e.g., the input devices 211a, 211b of FIG. 3) disposed in the first housing, and an output device (e.g., the display 221 of FIG. 3) disposed in the second housing.

According to an embodiment, the input device may include a touchscreen display.

According to an embodiment, the bracket may include a sleeve (e.g., the sleeve 323a of FIG. 6) coupled to surround the outer circumferential surface of the hollow shaft and configured to rotate, and a first fixing plate (e.g., the first fixing plate 323b of FIG. 6) extending from the sleeve and configured to pivot around the hollow shaft as the sleeve rotates.

According to an embodiment, the at least one link member may include a hub portion (e.g., the hub portion 325a of FIG. 6) bound or fixed to one of two opposite ends of the shaft, and a second fixing plate (e.g., the second fixing plate 325b of FIG. 6) extending from the hub portion and disposed to at least partially face the first fixing plate.

According to an embodiment, the hinge assembly may further include a fastening member (e.g., the fastening member 399 of FIG. 6) disposed to pass through the first fixing plate and the second fixing plate, thereby fixing the first fixing plate and the second fixing plate in a state facing each other.

According to an embodiment, the hollow shaft may include a slit (e.g., the second slit 415a of FIG. 13 or 14) extending along the direction of the hinge axis.

Although the disclosure has been described by illustrating one embodiment, it should be understood that one embodiment is for illustration and does not limit the disclosure. It is apparent to those skilled in the art that various changes in form and detailed configuration may be made without departing from the overall scope of the disclosure, including the appended claims and their equivalents. For example, in areas that directly rub during rotation or pivoting operation (e.g., the outer circumferential surface of the shaft, the inner circumferential surface and outer circumferential surface of the hollow shaft, and/or the inner circumferential surface of the sleeve), a reinforcing coating for preventing wear (e.g., diamond-like carbon (DLC) coating) may be provided, and by processing the edges of the shaft or hollow shaft into inclined or curved surfaces, interference phenomena (e.g., scratching of contact areas) during rotation operation may be suppressed.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A hinge assembly, comprising:
a fixing member including a hollow shaft extending along a direction of a hinge axis;
a shaft accommodated at least partially in the hollow shaft and configured to rotate around the hinge axis within the hollow shaft;
a bracket coupled to surround at least a portion of the hollow shaft and configured to rotate around the hinge axis; and
at least one link member, wherein a portion of the at least one link member is coupled to the shaft, and another portion of the at least one link member is fixed to the bracket,
wherein the shaft and the bracket are connected through the at least one link member to rotate together with respect to the hollow shaft.

2. The hinge assembly of claim 1,
wherein the shaft is configured to rub against an inner circumferential surface of the hollow shaft, and
wherein the bracket is configured to rub against an outer circumferential surface of the hollow shaft.

3. The hinge assembly of claim 2, wherein the bracket comprises:
a sleeve coupled to surround the outer circumferential surface of the hollow shaft and configured to rotate; and
a first fixing plate extending from the sleeve and configured to pivot around the hollow shaft as the sleeve rotates.

4. The hinge assembly according to claim 3, wherein the sleeve is configured to rub against the outer circumferential surface of the hollow shaft as the bracket rotates.

5. The hinge assembly of claim 3, wherein the bracket further comprises:
at least one first fastening hole provided on the first fixing plate in an area facing the link member; and
at least one second fastening hole disposed adjacent to the at least one first fastening hole.

6. The hinge assembly of claim 3, wherein the at least one link member comprises:
a hub portion bound or fixed to one of two opposite ends of the shaft; and
a second fixing plate extending from the hub portion and disposed at least partially to face the first fixing plate.

7. The hinge assembly of claim 6, wherein the second fixing plate is fixed to the first fixing plate while facing the first fixing plate.

8. The hinge assembly of claim 6, wherein the at least one link member further includes a third fastening hole provided to pass through the second fixing plate.

9. The hinge assembly of claim 8, further comprising a fastening member fixed to the first fixing plate while passing through the third fastening hole.

10. The hinge assembly of claim 1, wherein the hollow shaft includes a slit extending along the direction of the hinge axis.

11. The hinge assembly of claim 1,
wherein the fixing member comprises:
a third fixing plate extending along the direction of the hinge axis, and
a fixing boss provided at one end of the third fixing plate, and
wherein the hollow shaft is bound or fixed to the fixing boss.

12. The hinge assembly of claim 11, wherein one end of the shaft protrudes from one end of the hollow shaft, and the other end of the shaft protrudes from the other end of the hollow shaft and protrudes to one side of the fixing boss.

13. The hinge assembly of claim 11, wherein the hollow shaft includes a D-shaped plane provided on an outer circumferential surface of a portion bound to the fixing boss.

14. An electronic device, comprising:
a first housing;
a second housing configured to pivot around a hinge axis between a first position facing the first housing and a second position unfolded by a designated angle from the first position; and
a hinge assembly rotatably coupling the first housing and the second housing, the hinge assembly including:
a fixing member disposed at least partially in one of the first housing and the second housing and including a hollow shaft extending along a direction of a hinge axis,
a shaft accommodated at least partially in the hollow shaft and configured to rotate around the hinge axis within the hollow shaft,
a bracket disposed at least partially in the other one of the first housing and the second housing and coupled to surround at least a portion of the hollow shaft and configured to rotate around the hinge axis, and
at least one link member, wherein a portion of the at least one link member is coupled to the shaft, and another portion of the at least one link member is fixed to the bracket,
wherein the shaft and the bracket are connected through the at least one link member to rotate together with respect to the hollow shaft.

15. The electronic device of claim 14, further comprising:
an input device disposed in the first housing; and
an output device disposed in the second housing.

16. The electronic device of claim 14, further comprising a display coupled to the first housing and the second housing and including a folding area over the hinge assembly.

17. The electronic device of claim 14,
wherein the shaft is configured to rub against an inner circumferential surface of the hollow shaft, and
wherein the bracket is configured to rub against an outer circumferential surface of the hollow shaft.

18. The electronic device of claim 17, wherein the bracket comprises:
a sleeve coupled to surround the outer circumferential surface of the hollow shaft and configured to rotate; and
a first fixing plate extending from the sleeve and configured to pivot around the hollow shaft as the sleeve rotates.

19. The electronic device of claim 18, wherein the bracket further comprises:
at least one first fastening hole provided on the first fixing plate in an area facing the link member; and
at least one second fastening hole disposed adjacent to the at least one first fastening hole.

20. The electronic device of claim 19, further comprising another hinge assembly coupled to the hinge assembly in parallel.
